(19) United States
(12) Patent Application Publication
(10) Pub. No.: US 2005/0263801 A1
(43) Pub. Date: Dec. 1, 2005

(54) Phase-change memory device having a barrier layer and manufacturing method

(76) Inventors: Jae-Hyun Park, Gyeonggi-do (KR); Sung-Min Kim, Incheon (KR); Yoon-Jong Song, Seoul (KR); Su-Youn Lee, Gyeonggi-do (KR); Young-Nam Hwang, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/086,246

(22) Filed: Mar. 21, 2005

Related U.S. Application Data
(63) Continuation-in-part of application No. 11/027,255, filed on Dec. 30, 2004.

(30) Foreign Application Priority Data
May 27, 2004 (KR) 2004-37965
Jul. 2, 2004 (KR) 2004-51732

(51) Int. Cl. H01L 29/772; H01L 21/8234

(52) U.S. Cl. 257/288; 438/238; 257/379; 438/95

(57) ABSTRACT

A semiconductor device comprises a semiconductor substrate having an isolation region that defines an active region. The active region has a planar surface and a non-planar surface that extends from the planar surface. The device further includes a gate dielectric layer covering the non-planar surface and a first gate electrode extending across the non-planar surface with the gate dielectric layer therebetween. In addition, a source and drain region are formed on opposite sides of the gate electrode. According to an aspect of the present invention, the resulting device has a non-planar channel region extending between the source region and the drain region. The non-planar channel region is formed along the non-planar surface described above. Further, programmable resistance element is electrically coupled to the drain region to form a phase-change memory device.

This application is a continuation-in-part of the U.S. patent application Ser. No. 11/027,255, filed on Dec. 30, 2004, which claims priority from Korean Patent Application No. 2004-37965, filed on May 27, 2004, and also claims priority from Korean Patent Application No. 2004-51732, filed on Jul. 2, 2004, the disclosures of which are incorporated herein in their entirety by reference.

### BACKGROUND OF THE INVENTION

1. Field of the Invention

The present invention relates to a semiconductor memory device and methods of fabricating the same, and more particularly, to a phase-change memory device with a high driving current capability, and methods of fabricating the same.

2. Description of Related Art

The use of phase-changeable materials for electronic memory applications is known in the art and is disclosed, for example, in U.S. Pat. No. 6,147,395 and U.S. Pat. No. 6,337,266. The two states of a memory, in the case of phase-changeable memory, depend on the resistance to current flow in a memory cell. The phase-changeable material typically has an amorphous phase and a crystalline phase, with inherent high and low electrical resistance, respectively. The amorphous phase exists at relatively high temperatures, and the crystalline phase exists at relatively low temperatures. Phase-changeable memory operates on the basic idea that memory cell states, i.e., “on” or “off”, are dependent on temperature. Thus, means for setting the temperature high or low is incorporated in each memory cell.

A general structure for this type of memory includes a phase-changeable material sandwiched between a lower electrode and an upper electrode. The lower electrode typically plays two roles, one being the conduction electrode to the memory cell, and the other being an ohmic heater to control the phase of the phase-changeable material. As just described, the structure comprises interfaces between the top electrode and the phase-changeable material, and between the bottom electrode and the phase-changeable material. During a fabrication of the memory device, and during its operational life in use, these interfaces may become contaminated or oxidized. Such oxidation causes a large variation in the distribution of contact resistances at these interfaces. Since the operation of phase-changeable memory depends on distinguishing between the memory cell being “on” or “off” based on the cell's resistance to current flow, contamination or oxidation jeopardizes the accuracy of memory programming. A need still remains for a novel phase-change memory structure that can prevent such contamination or oxidation and the manufacturing method thereof.

On the other hand, as the integration of the semiconductor device increases, the MOS transistors are continuously scaled down. As a result, a drive current capacity becomes limited and a short channel effect occurs. Accordingly, a need exists for increasing a drive current capacity of semiconductor devices such as phase-change memory devices.

### SUMMARY OF THE INVENTION

In one embodiment, a semiconductor device comprises a semiconductor substrate having an isolation region that defines an active region. The active region has a planar surface and a non-planar surface that extends from the planar surface. The device further includes a gate dielectric layer covering the non-planar surface and a first gate electrode extending across the non-planar surface with the gate dielectric layer therebetween. In addition, a first impurity region and a second impurity region are formed on opposite sides of the gate electrode. According to an aspect of the present invention, the resulting device has a non-planar channel region extending between the source region and the drain region. The non-planar channel region is formed along the non-planar surface described above. Further, programmable resistance element electrically coupled to one of the first impurity region and second impurity region to form a phase-change memory device.

### BRIEF DESCRIPTION OF THE DRAWINGS

FIG. 1 is a schematic view of an embodiment that features a phase-change memory cell array of an embodiment of the invention.

FIG. 2 is a plan view of part of a phase-change memory cell array area and peripheral circuit area according to an embodiment of the invention.

FIGS. 3A-9A and 10-14 are cross-sectional views taken along line I-I′ of FIG. 2, and FIGS. 3B-9B are cross sectional views taken along line II-II′ of FIG. 2, showing processing steps of manufacturing an embodiment of the invention.

FIG. 4C is a plan view of the reverse fin mask patterns 105c′ according to another embodiment of the present invention.

FIG. 15 is a cross-sectional view of a phase change memory cell array and a peripheral circuit according to another embodiment of the invention.

FIG. 16 is a plan view of a photoresist mask pattern to form four trench mask patterns.

FIG. 17 is a cross sectional view of a non-planar type phase change memory device according to another embodiment of the present invention.

FIG. 18 is a cross sectional view of a non-planar type phase change memory device according to yet another embodiment of the present invention.

FIG. 19 is a schematic block diagram of a portable electronic apparatus adopting an embodiment of the phase-change memory device of the invention.

FIG. 20 is a graph showing the lower electrode contact resistance characteristic between a phase-change material and a lower electrode of the phase-change resistors manufactured according to table (1).

FIG. 21 is a graph showing a programming characteristic of a conventional phase-change memory device without an oxygen barrier layer.

FIG. 22 is a graph showing a programming characteristic of a phase-change memory device of an embodiment of the invention with an oxygen barrier layer.

### DETAILED DESCRIPTION OF THE PREFERRED EMBODIMENTS

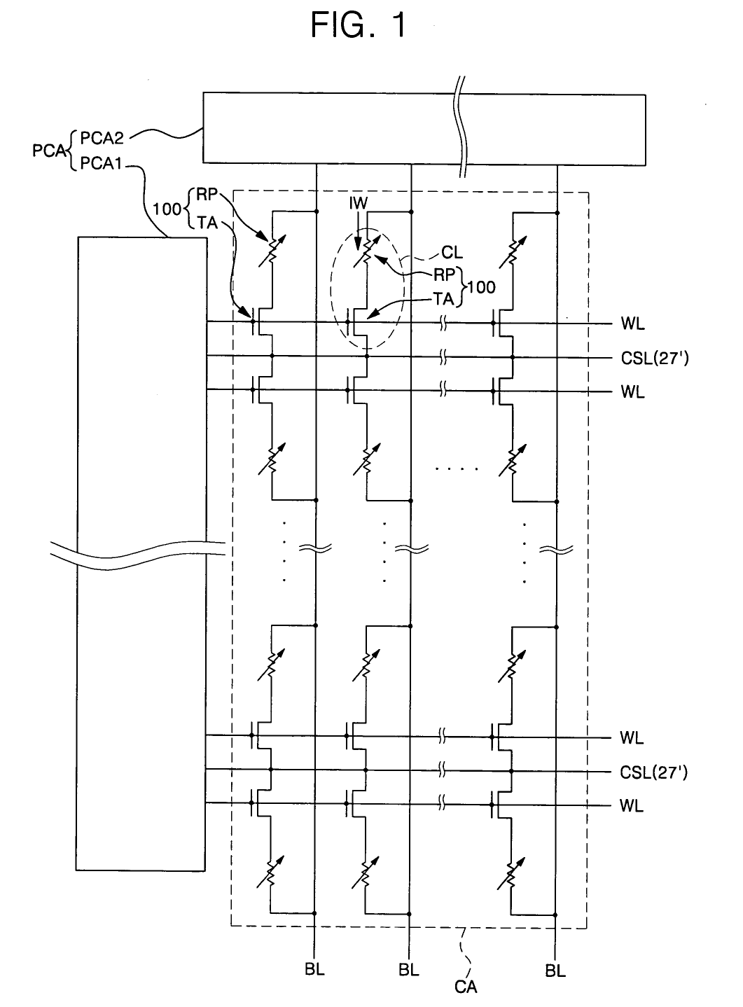

FIG. 1 is a schematic view of an embodiment that features a phase-change memory cell array CA and a peripheral circuit area PCA of the present invention. The cell array area CA comprises an array of memory cells CL each of which in turn comprises an access transistor TA and a phase-change resistor RP. Each memory cell CL is connected to a bit line BL, a word line WL, and a common source line CSL in a configuration that is known in the art. Other conventional structures will be included in the present invention. For example, the peripheral circuit area PCA includes first and second integrated circuits PCA1, PCA2 to drive the memory cells CL. The state of a memory cell CL is determined by an amount of a writing current IW. Reading of the state of the memory cell CL is performed by current sensing and other functions of memory control are known to one skilled in the art.

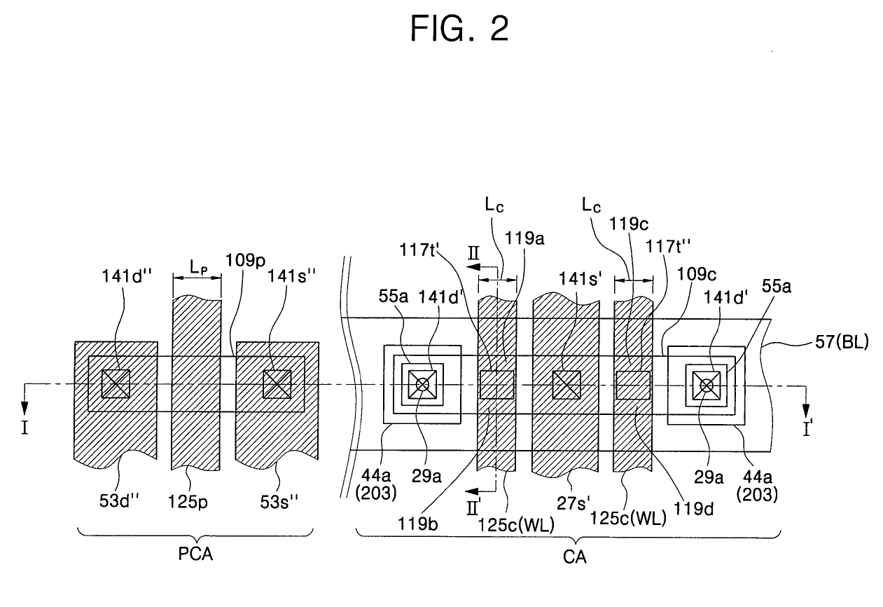

FIG. 2 is a plan view of a portion of a phase-change memory cell array area CA and a portion of a peripheral circuit area PCA according to an embodiment of the invention.

Referring to FIG. 2, a relative configuration of a cell active region 109c and a peripheral circuit active region 109p are shown. In the cell array area CA, a common source line 27s′ extends across the cell active region 109c while overlapping a first source contact hole 141s′ in the cell active region 109c in parallel with cell gate electrodes 125c (WL) having a width of L_{c}. In addition, a bit line 57 (BL) is formed above the cell gate electrodes 125c and extends across the cell gate electrodes 125c. Pin trenches 117t′ and 117t″ are formed in the cell active region 109c according to one embodiment of the present invention. As a result, first channel fins 119a, 119b and second channel fins 119c, 119d are also formed in the cell active region 109c. Further, a bit line contact hole 55a is formed to be connected to the bit line 57. Also, a phase-change resistor 44a (or an upper electrode pattern 203) overlaps a first drain contact hole 141d′ and a phase-change resistor contact hole 29a that are formed in the cell active region 109c.

On the other hand, in the peripheral circuit active region 109p, shown on the left side of FIG. 2, a peripheral circuit gate electrode 125p having a width of Lₚ is formed. Further, a peripheral circuit drain region 53d″ and a peripheral circuit source region 53s″ are formed on opposite sides of the peripheral circuit gate electrode 125p. In addition, a second source contact hole 141s″, and a second drain contact hole 141d″ are formed in the peripheral circuit active region 125p. The details of these elements will be explained later.

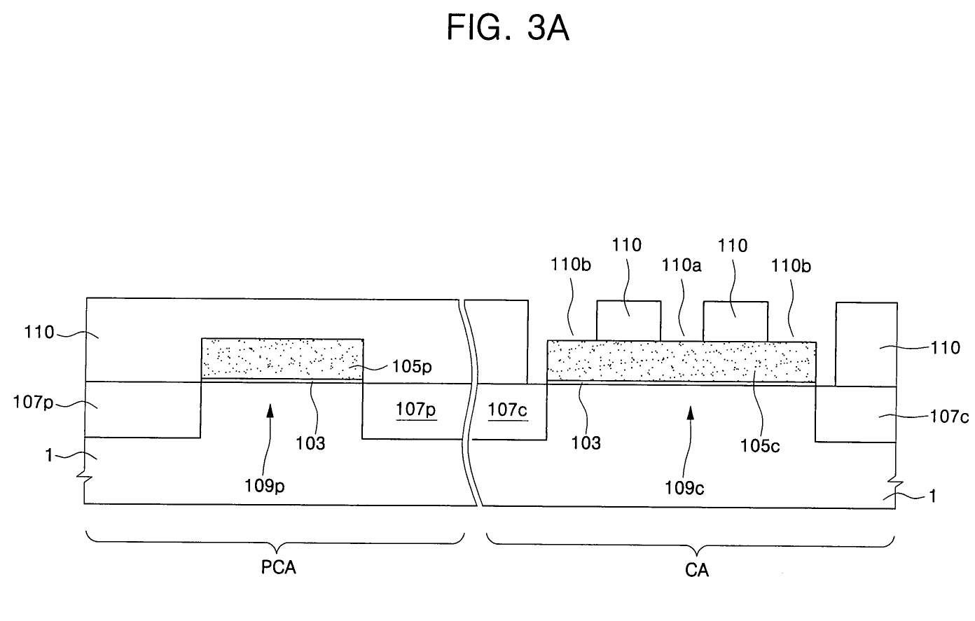

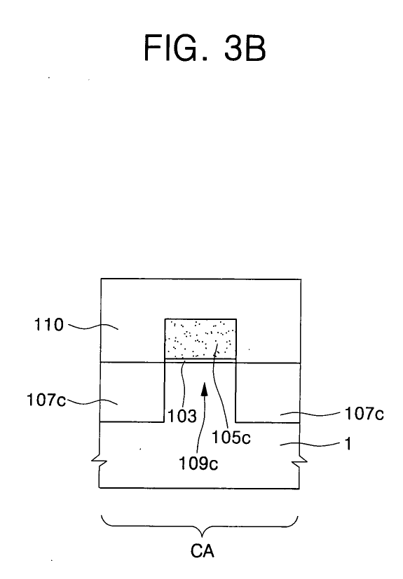

FIGS. 3A-9A are cross-sectional views taken along line I-I′ of FIG. 2, and FIGS. 3B-9B are cross sectional views taken along line II-II′ of FIG. 2, showing processing steps of manufacturing a semiconductor device according to one embodiment of the invention.

Referring to FIGS. 3A and 3B, trench isolation layers, i.e., a peripheral trench isolation layer 107p and a cell trench isolation layer 107c, are formed on the semiconductor substrate 1, using conventional isolation techniques. In particular, a cell trench mask pattern 105c and a peripheral circuit trench mask pattern 105p are respectively formed in the cell active region 109c and the peripheral circuit active region 109p overlying a pad oxide layer 103 to form isolation trenches in the semiconductor substrate 1. The trench mask patterns 105c and 105p are formed using dielectric materials such as nitride. The isolation trenches are formed by etching the semiconductor substrate 1 using the trench mask patterns 105c and 105p. Then, the isolation trenches are filled with a conventional trench isolation material and planarized using techniques such as chemical mechanical polishing (CMP) to complete the cell trench isolation layer 107c and the peripheral circuit isolation layer 107p.

A photoresist pattern 110 subsequently covers the peripheral circuit area PCA and a portion of the cell trench isolation layer 107c. The photoresist pattern 110 has a center opening portion 110a and end opening portions 110b to expose the cell trench mask pattern 105c in the cell array area CA.

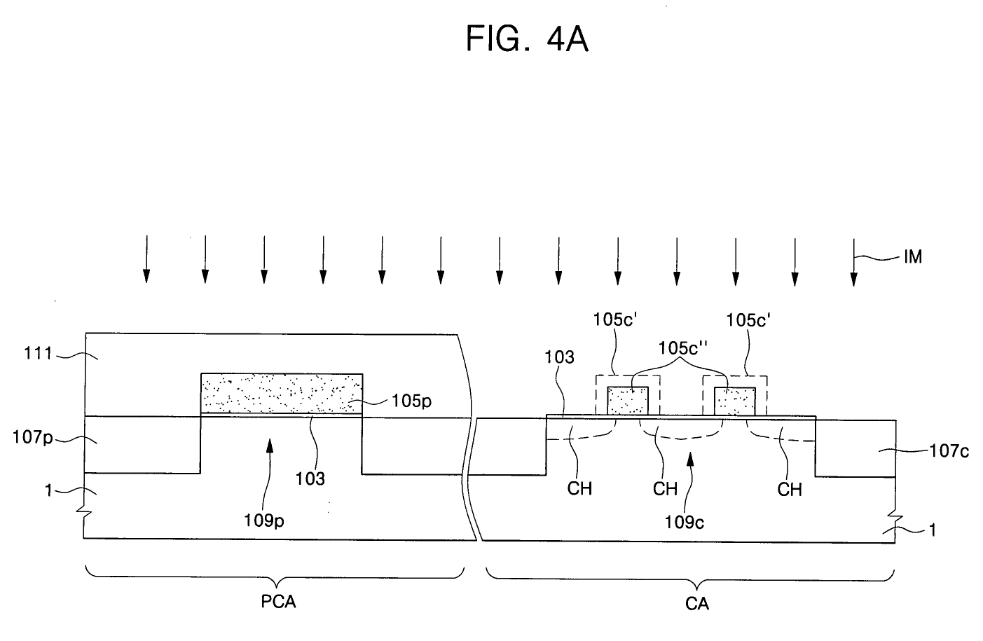

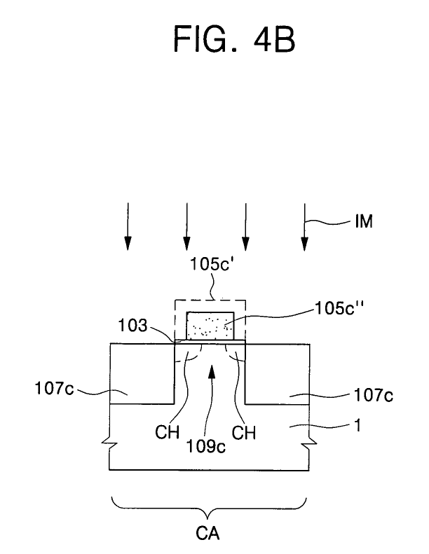

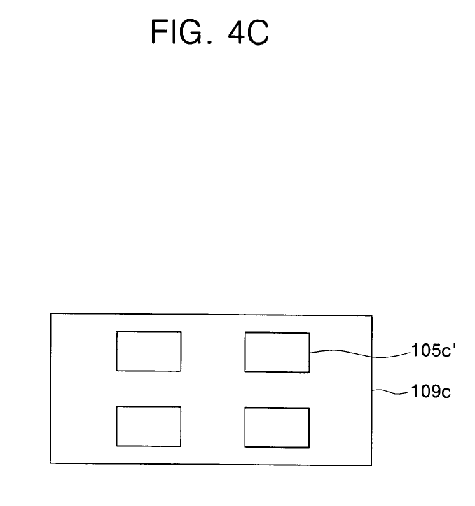

Referring to FIGS. 4A and 4B, in one embodiment, a pair of preliminary reverse fin mask patterns 105c′ are formed on the cell active region 109c by etching the cell trench mask pattern 105c using the photoresist pattern 110 as an etching mask. The fin mask patterns 105c′ may also be formed in a pattern of four, as shown in FIG. 4c.

A second photoresist pattern 111 is formed to cover the peripheral circuit area PCA, while leaving the cell array area CA exposed. A reverse fin mask pattern 105c″ is formed by isotropically etching the preliminary reverse patterns 105c′ using an etchant, for example, H₃PO₄. Accordingly, the width of a fin structure to be formed later can be made less than a photolithography resolution limit.

Then, ion implantation may be performed on the resulting structure, using impurities IM such as B, or BF₂ to adjust a Vth of the transistor to be formed, thereby forming doped regions CH. Subsequently, the second photoresist pattern 111 is removed.

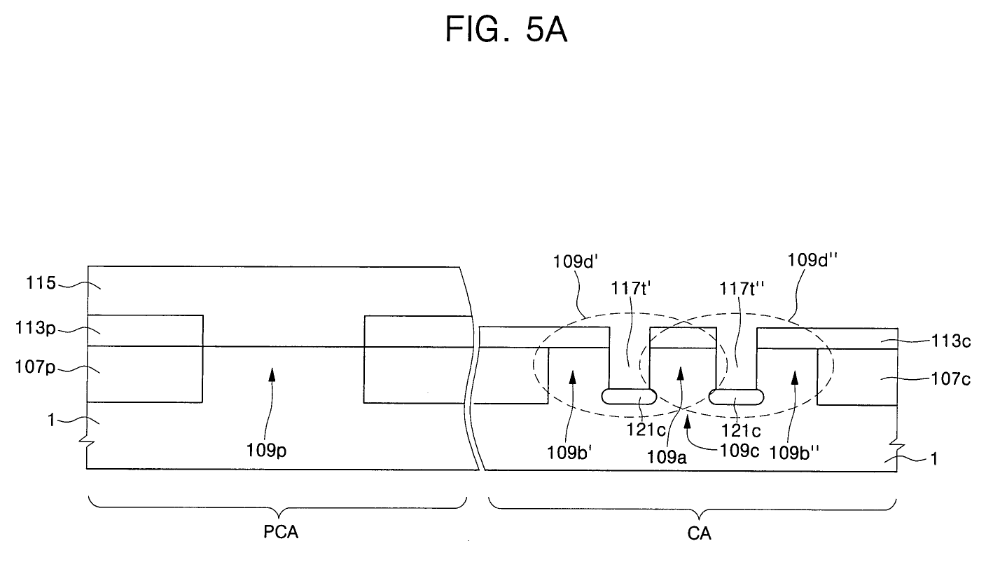

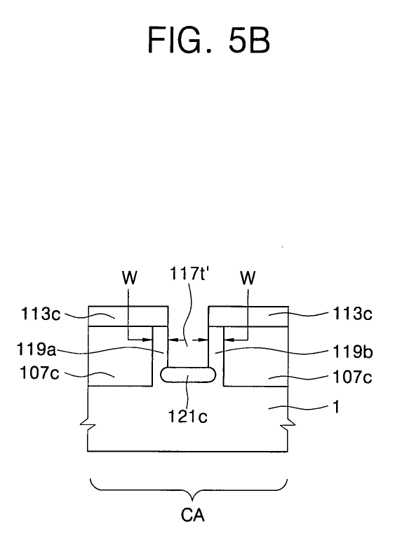

Turning to FIGS. 5A and 5B, an insulating layer is formed over the resulting structure and subsequently planarized to expose the reverse fin mask pattern 105c″ (not shown). The peripheral trench mask pattern 105p and the reverse fin mask pattern 105c″ are then removed, thereby forming an insulating layer pattern 113p on the peripheral trench isolation layer 107p and a fin mask pattern 113c on the cell trench isolation layer 107c.

Next, a third photoresist pattern 115 is formed to cover the peripheral circuit area PCA, while exposing the cell array area CA.

The semiconductor substrate 1 of the cell active region 109c is then etched, using a third photoresist pattern 115 and the fin mask pattern 113c as an etch mask, to form a pair of fin trenches 117t′ and 117t″. As shown in FIG. 2, the pair of fin trenches 117t′ and 117t″ define a first pair of channel fins 119a and 119b and a second pair of channel fins 119c and 119d, which are connected by a first connection portion 109a corresponding to a central portion of the cell active region 109c to form fin bodies 109d′, 109d″. A pair of second connection portions 109b′ and 109b″ are formed corresponding to edge portions of the cell active region 109c. The width of the channel fins 119a, 119b (FIG. 5B) are determined by the width of the fin trench mask 117t, 177t″ at a size less than the photolithography resolution limit.

In one aspect of the present invention, a channel stop layer 121c may be formed in the substrate 1 under bottom portions of the fin trench 117t′, 117t″.

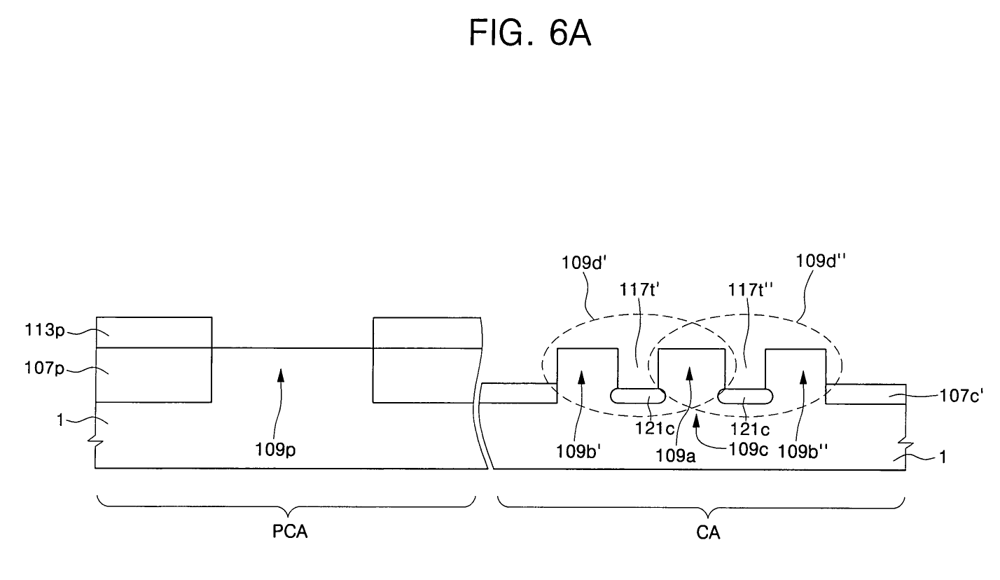

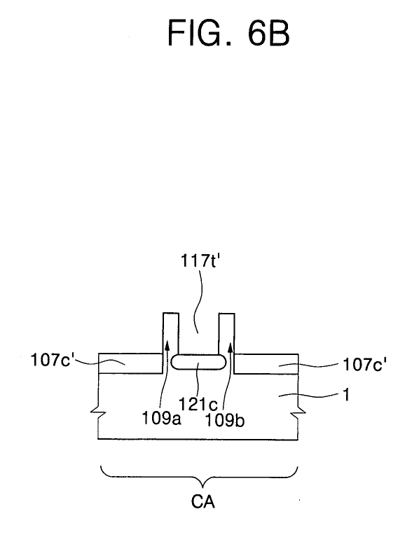

Referring to FIGS. 6A and 6B, after the third photoresist pattern 115 is removed, the fin mask pattern 113c is also removed. After the fin mask pattern 113c is removed, additionally an ion implantation process may be performed on the semiconductor substrate 1 to control the threshold voltage Vₜₕ of the MOSFET in the cell active region 109c if the ion implantation process IM described above with reference to FIG. 4A is omitted.

Also, the cell trench isolation layer 107c is partially etched or recessed to expose a sidewall of the cell active region 109c to thereby form double fin bodies 109d′ and 109d″. As described above, the double fin bodies 109d′ and 109d″ comprise the first pair of channel fins 119a and 119b (FIG. 2) and the second pair of channel fins 119c and 119d (FIG. 2) connected by the first connection portion 109a. The second connection portions 109b′ and 109b″ (FIG. 6A) are formed along opposite sides of the first connection portion 109a. One fin body may comprise a pair of channel fins, (e.g., 119a and 119b; or 119c and 119d) and first and second connection portions 109a, 109b′ and 109b″.

The insulating layer 113p on the peripheral trench isolation layer 107p and the pad oxide layer 103 may be etched during the partial removal of the first cell trench isolation layer 107c. Additionally, the peripheral trench isolation layer 107p may be removed partially to form a fin body (not shown).

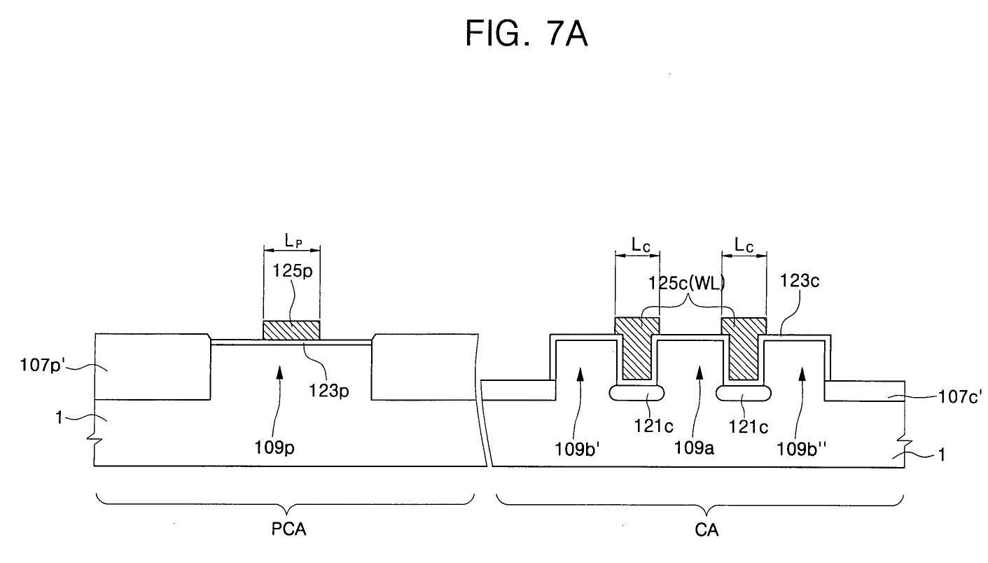

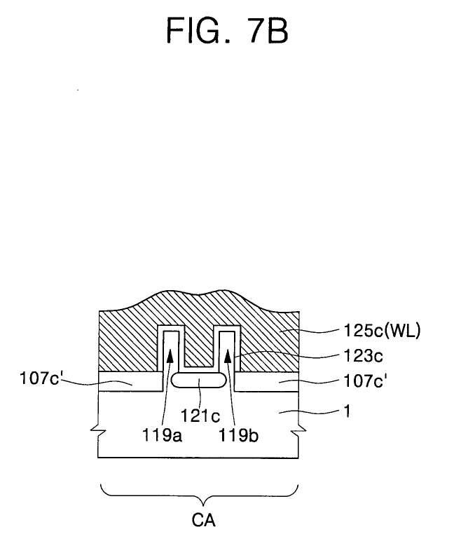

Referring to FIGS. 7A and 7B, a cell gate dielectric layer 123c and a peripheral circuit gate dielectric layer 123p; and the cell gate electrode 125c and the peripheral circuit gate electrode 125p are formed on the fin bodies 109d′ and 109d″ (FIG. 6A), using techniques known in the art.

In detail, the cell gate electrode 125c and the peripheral gate electrode 125p are respectively formed on the cell gate dielectric layer 123c and on the peripheral gate dielectric layer 123p. Preferably, the widths of the cell gate electrode 125c and the peripheral gate electrode 125p may be different. More preferably, the width Lₚ of the peripheral circuit gate electrode 125p is at least about 1.5 times greater than the width L_{c} of the cell gate electrode 125c.

Furthermore, the peripheral circuit gate dielectric layer 123p may be formed to be thicker than the cell gate dielectric layer 123c.

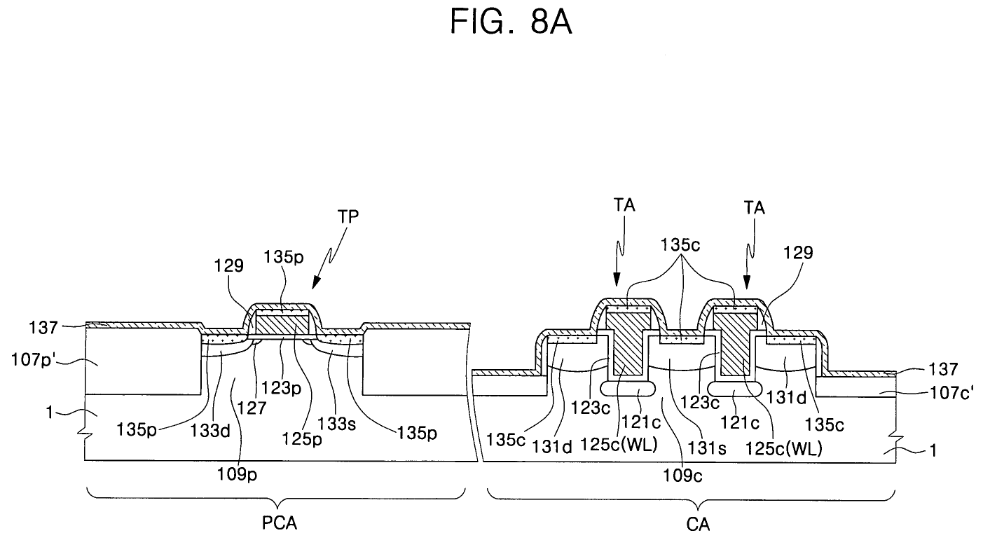

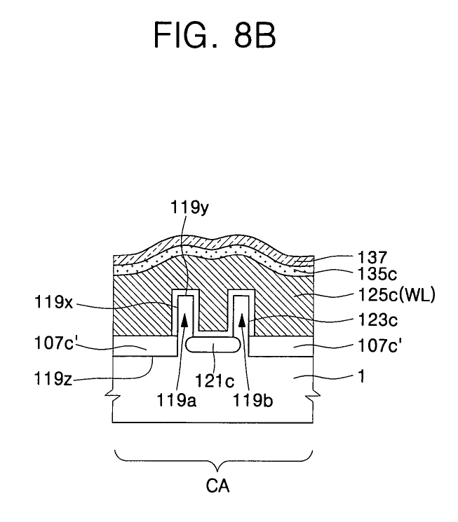

Referring to FIG. 8A, a peripheral circuit MOS transistor TP and a cell access MOS transistor TA are formed on the semiconductor substrate 1. In detail, a p-type second low concentration impurity region 127 is formed in the peripheral circuit active region 109p, using the peripheral gate electrode 125p as an ion implantation mask.

Also, a gate spacer 129 of a conventional spacer material, such as an oxide or nitride, is preferably formed along opposite sides of the cell gate electrode 125c and also along opposite sides of the peripheral gate electrode 125p, using conventional techniques.

Next, using the gate spacer 129, a first impurity region, e.g., an n-type first source region 131s and a second impurity region, e.g., an n-type first drain region 131d are formed in the cell active region 109c. In addition, a p-type second source region 133s, a p-type second drain region 133d are formed in the peripheral circuit active region 109p, using the methods known in the art.

As a result, a pair of access (switching) MOS transistors TA are formed in the cell area CA and a peripheral MOS transistor TP is formed in the peripheral circuit area PCA. The pair of access MOS transistors TA may be a non-planar type, e.g., the fin type transistor and the peripheral MOS transistor is a planar-type transistor.

A silicide layer 135p may be formed on at least one of the second source and drain regions 133s and 133d and the peripheral circuit gate electrode 125p. A silicide layer 135c may be formed on at least one of the first source and drain regions 131s and 131d and the cell gate electrode 125c. Then, a lower etch stopper 137 is formed over the resulting structure.

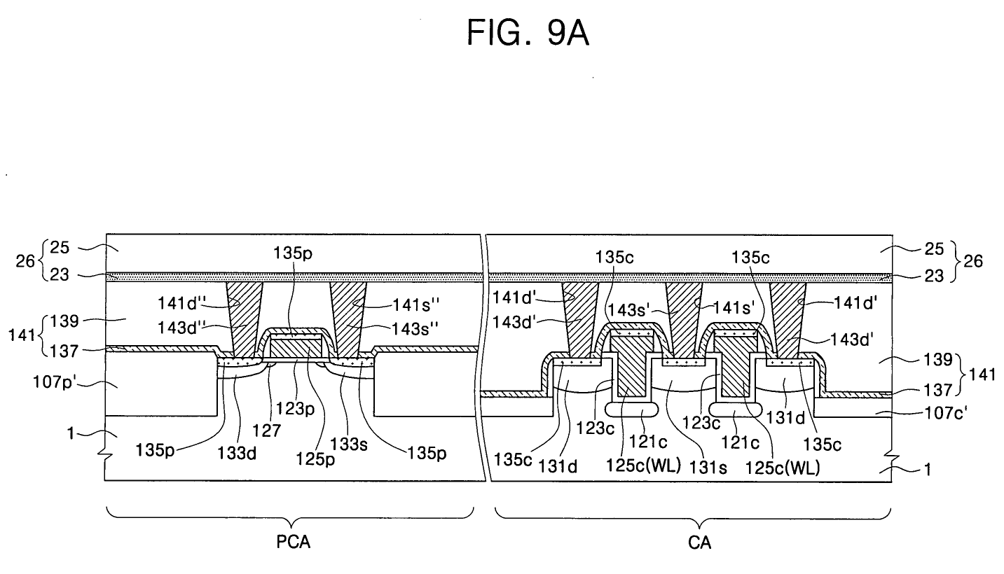

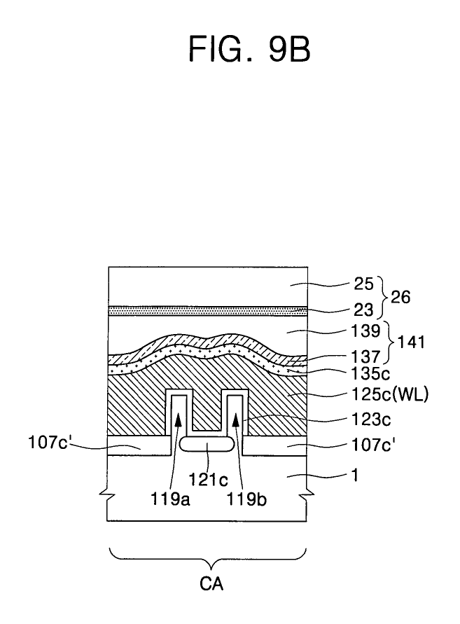

Referring to FIG. 9A, a lower insulating layer 139 is formed over the lower etch stopper 137, both of which are combined to form a lower inter-level insulating layer 141.

Subsequently, the first source contact hole 141s′, the first drain contact hole 141d′ are formed in the lower inter-level insulating layer 141 in the cell area CA. Then, a first source contact plug 143s′ and a first drain contact plug 143d′ are respectively formed in the first source contact hole 141s′, the first drain contact hole 141d′, using the methods known in the art. Also, the second source contact hole 141s″, the second drain contact hole 141d″, a second source contact plug 143s″, and a second drain contact plug 143d″ are formed in the peripheral circuit area PCA in the lower inter-level insulating layer 141, using the conventional techniques.

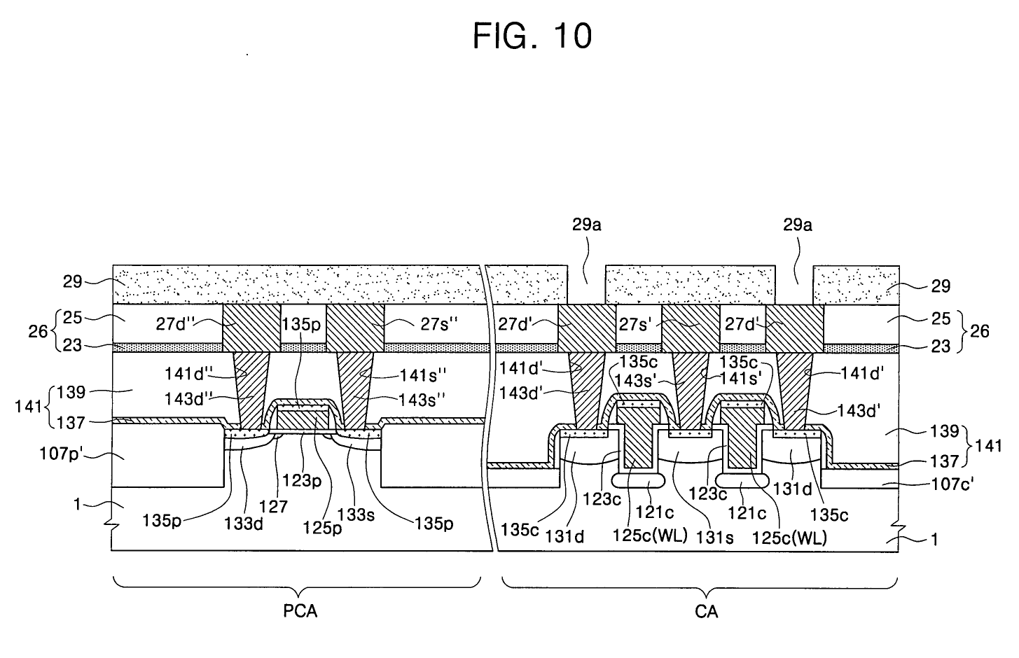

Then, an upper inter-level insulating layer 26 is formed, comprising an upper etch stopper 23 and an upper insulating layer 25. Referring to FIG. 10, a common source line 27s′, which represents a cross-section of the common source line 27s′ in FIG. 1b, a first drain pad 27d′, a peripheral circuit region source pad 27s″, and a peripheral circuit region drain pad 27d″ are formed within the upper inter-level insulating layer 26 shown in FIG. 9. These elements are formed according to processes known to one skilled in the art. Consequently, the common source line 27s′ and the first drain pad 27d′ are respectively electrically connected to the first source region 13s′ and the first drain region 13d′.

Afterwards, a molding layer 29 is formed on the resulting structure. A phase-change resistor contact hole 29a is then formed in the molding layer 29, using photolithography and etching processes. The molding layer 29 may be preferably formed of a material having a high thermal conductivity. For example, the molding layer 29 has a thermal conductivity higher than that of silicon oxide. This gives a high rapid quenching efficiency of a phase transition of a phase-changeable material pattern, in addition to an oxygen barrier characteristic to prevent the phase-changeable material pattern from being oxidized. Such materials include silicon nitride and silicon oxynitride, for example.

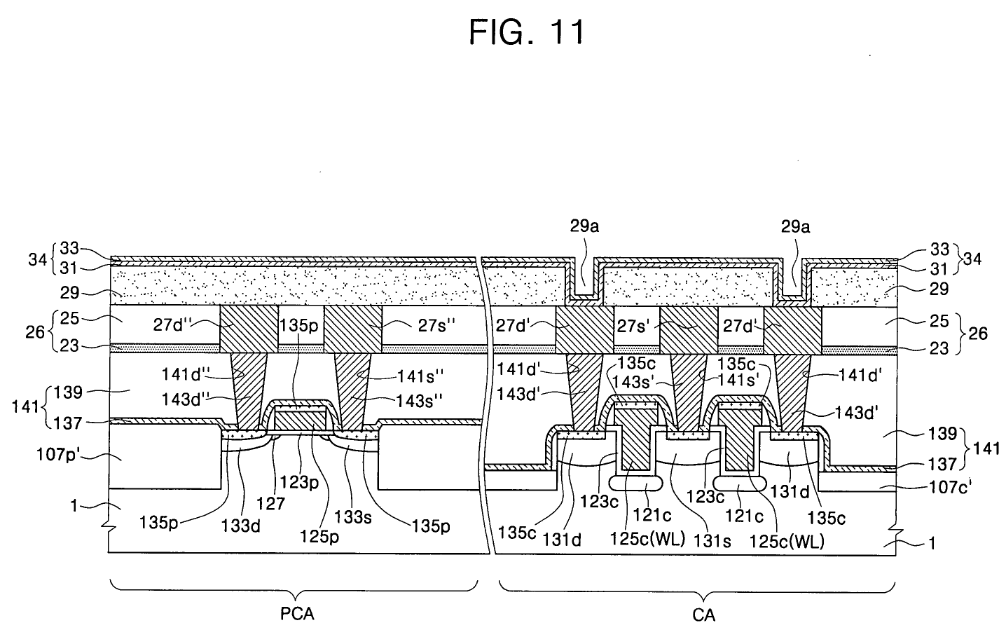

Turning to FIG. 11, a conformal contact spacer layer 34 may be formed of either one or two layers. Preferably, the conformal contact spacer layer 34 is formed under vacuum without using an oxygen gas. If the oxygen gas is used to form the conformal contact spacer layer 34, to prevent the oxidation of the drain pad 27d, it is preferable to use a lower formation temperature. The conformal contact spacer layer 34 may be a silicon nitride layer formed using plasma-enhanced (PE) CVD, or low-pressure (LP) CVD. The conformal contact spacer layer 34 may be formed of two layers, comprising a lower contact spacer layer 31 of a silicon oxynitride layer formed by using PE-CVD at less than about 500° C., and an upper contact spacer layer 33 of silicon nitride formed by using LP-CVD at greater than about 500° C.

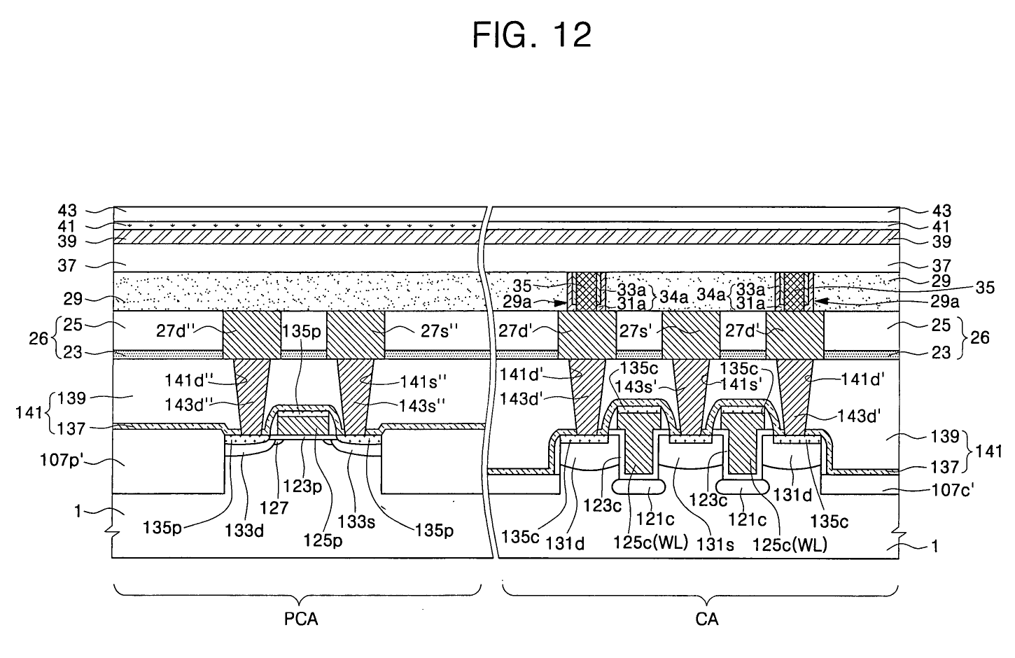

Referring to FIG. 12, the conformal contact spacer layer 34 is anisotropically etched to expose the first drain pad 27d′. As a result, a contact spacer 34a including an inner contact spacer 31a and an outer contact spacer 33a, is formed. The outer contact spacer 33a surrounds an outer wall of the inner contact spacer 31a.

Then, a lower electrode 35 is formed in the phase-change resistor contact hole 29a within the contact spacer 34a. The lower electrode 35 is electrically connected to the first drain pad 27d′, which is in turn electrically connected to the first drain region 131d of the switching transistor TA through first contact plug 143d′. In detail, the lower electrode 35 in the phase-change resistor contact hole 29a may be formed by depositing a conductive film such as a TiN film, or a TiAlN film overlying the molding layer 29 and within the contact hole 29a and by planarizing the conductive film until the molding layer 29 is exposed. As a result, the contact spacer 34a surrounds the sidewall of the lower electrode 35.

Subsequently, a phase-changeable material layer 37, an upper electrode layer 39, a glue layer 41, and a hard mask layer 43 are sequentially formed on the resulting structure including the molding layer 29. The hard mask layer 43 may be formed of SiO₂. The glue layer 41 may be a wetting layer such as SiN. One skilled in the art will, however, understand that the above-described structure is only a preferred embodiment and other suitable structures can also be used within the spirit and scope of the present invention. For example, the hard mask layer 43 can be formed using a dielectric material other than SiO₂.

The phase-changeable material layer 37 may be formed of a chalcogenide material, including, but not limited to, a GeSbTe alloy, or a Si or N doped GeSbTe alloy, with a thickness of, for example, about 1000 angstroms.

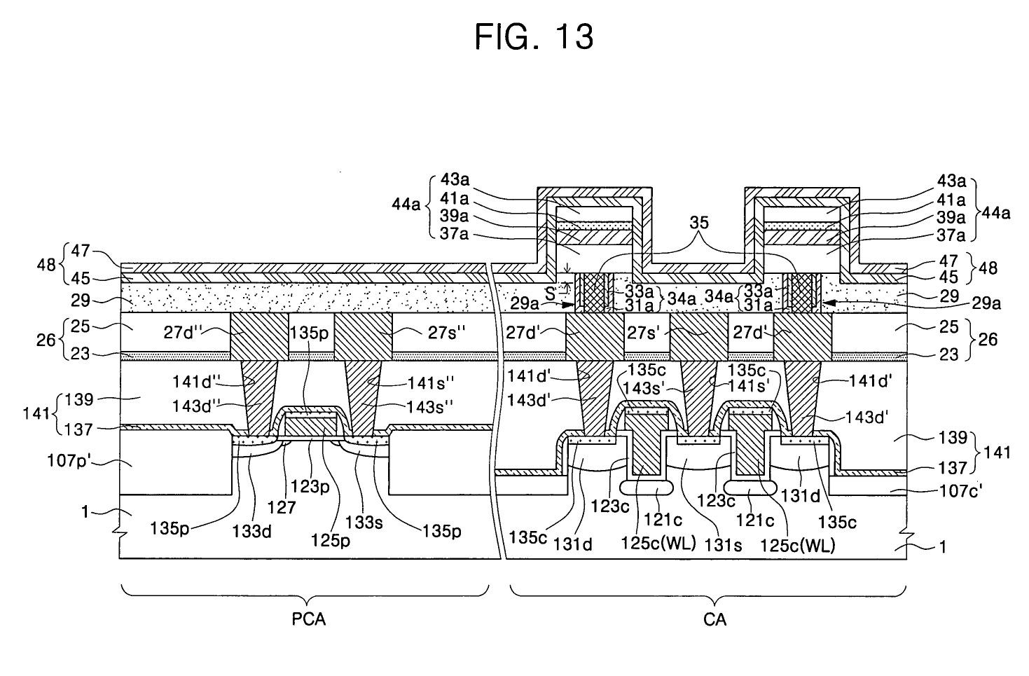

In FIG. 13, a phase-change resistor 44a may be formed by patterning the hard mask layer 43, the glue layer 41, the upper electrode layer 39, and the phase-changeable material layer 37 to form a hard mask layer pattern 43a, an upper electrode 39a, and a phase-changeable material pattern 37a, and then etching an upper portion of the molding layer 29 to thereby be completely separated from an adjacent phase-changeable material pattern 37a. This process also creates a protrusion portion 77 of the molding layer 29 that is self-aligned with the phase-change resistor 44a. The protrusion portion of the molding layer 29 results in a surface step difference indicated by symbol “S,” shown in FIG. 13. The phase-changeable material pattern 37a is electrically connected to the lower electrode 35.

Next, an oxidation barrier layer 48 may cover the resulting structure including the phase-change resistor 44a. The oxidation barrier layer 48 may comprise a single layer of nitride, for example, silicon nitride or silicon oxynitride, deposited using a PE-CVD process, or an atomic layer deposition (ALD) process at less than or equal to about 350° C. Alternatively, the oxidation barrier layer 48 may be formed of double layers, comprising a lower oxidation barrier layer 45 of nitride, such as silicon nitride or silicon oxynitride, deposited using a PE-CVD process or an ALD process at less than or equal to about 350° C.; and an upper oxidation barrier layer 47 of nitride, such as silicon nitride or silicon oxynitride, deposited using PE-CVD process or an LP CVD process at higher than or equal to about 350° C.

The oxidation barrier layer 48 prevents the phase-changeable material pattern 37a from being oxidized or contaminated by oxygen or impurities that may penetrate into an interface between the lower electrode 35 and the phase-changeable material pattern 37a, or another interface between the upper electrode 39a and the phase-changeable material pattern 37a during a process such as an oxide deposition (ILD deposition) to cover the phase-change resistor 44a.

Because the oxidation barrier layer 48 covers the sidewalls of the protrusion portion of the molding layer 29, as well as the sidewalls and/or the upper surface of the phase-change resistor 44a, penetration of oxygen into the phase-change resistor 44a can be efficiently blocked.

Additionally, a plasma nitridation process may be performed on the surface of the phase-change resistor 44a, using an N₂ or NH₃ gas at less than or equal to about 350° C. before forming the oxidation barrier layer 48.

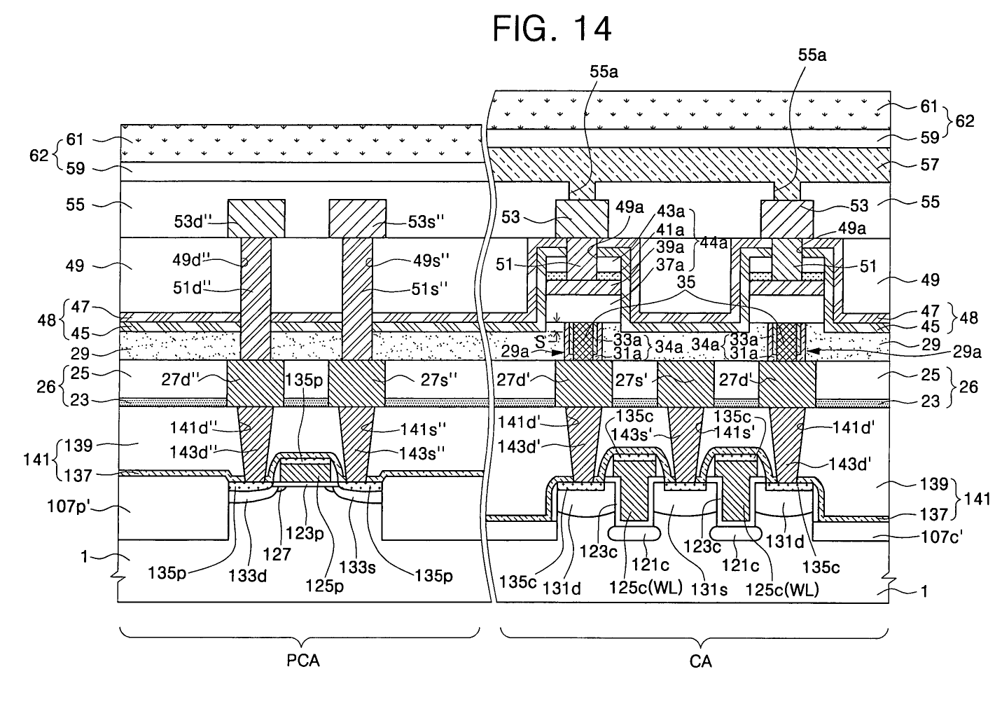

FIG. 14 shows the structure of FIG. 13 with the addition of a lower inter-metal dielectric (IMD) 49, an upper electrode contact hole 49a, an upper peripheral source pad contact hole 49s″, an upper peripheral drain pad contact hole 49d″, an upper electrode contact plug 51, a peripheral upper source plug 51s″, a peripheral upper drain plug 51d″, a bit line pad 53, a source metal line 53s″, a drain metal line 53d″, an upper IMD 55, a bit line contact hole 55a, and a bit line 57. These additional elements are added according to processes known to those familiar in the art.

Next, a passivation layer 62 including a silicon oxide layer 59 and a silicon nitride layer 61 is formed on the resulting structure to complete a phase-change memory device having the oxidation barrier layer 48.

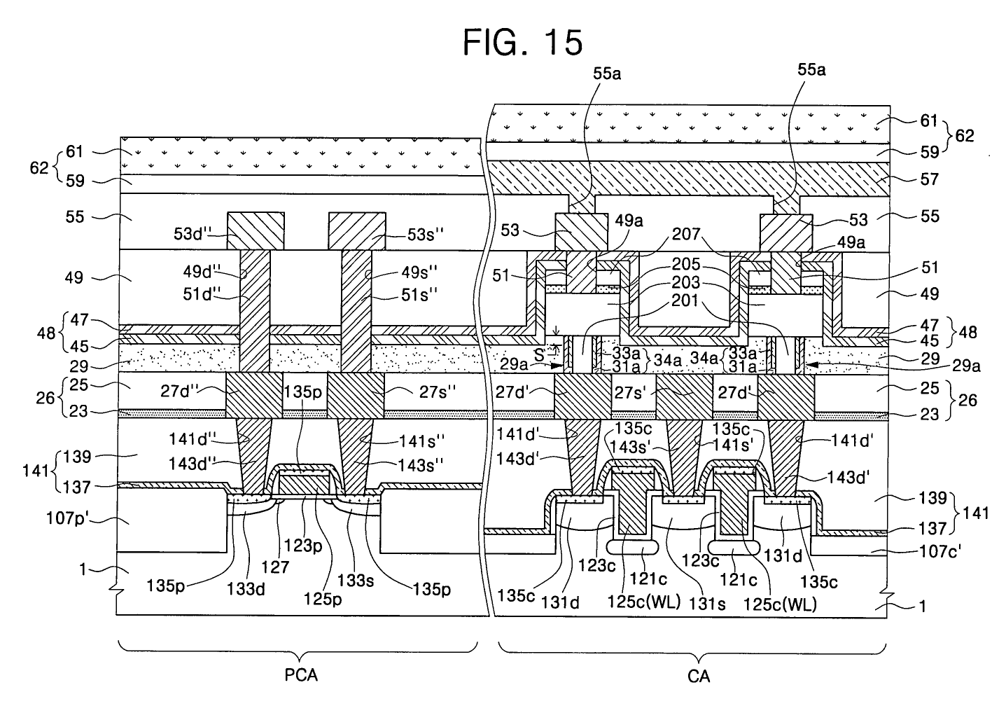

According to FIG. 15, the phase-change material pattern 201 is formed in the phase-change resistor contact hole 29a. An upper electrode pattern 203, a glue layer pattern 205, and a hard mask pattern 207 are sequentially formed on the phase change material pattern 201 and on a protrusion portion of the molding layer 29.

Consequently, the resulting phase-change memory device includes a semiconductor substrate 1 having an isolation region 107c that defines an active region 109c. The active region 109c has a planar surface and a non-planar surface that extends from the planar surface.

One example of such a non-planar surface is shown in FIG. 8B, in which the fins 119a and 119b each include sidewalls 119x and an upper surface 119y. The sidewalls 119x and the upper surface 119y form the non-planar surface that extends from the planar surface 119z. The phase-change memory device further includes, for example, the cell gate dielectric layer 123c covering the non-planar surface 119x, 119y, e.g., an upper surface and sidewalls of the fins 119a and 119b, and the gate electrode 125c extending across the non-planar surface 119x, 119y, with the gate dielectric layer 123c therebetween and across the planer surface 119z. In addition, the source and drain region 131s, 131d are formed on opposite sides of the gate electrode 125c.

Accordingly, the resulting phase-change memory device has a non-planar channel region extending between the source region 131s and the drain region 131d. The non-planar channel region is formed along the non-planar surface 119x, 119y, described above. Further, the programmable resistance element 44a (FIG. 14) is electrically coupled to the drain region 131d to form a phase-change memory device.

As is known, the drive current capacity is generally a simple function of a cross-sectional geometry of the conductive area. In the case of a field effect transistor (FET), the conductive area for the drive current is a channel region formed in an active area under a gate electrode and between a source and a drain. The geometry of the channel region is generally planar (“a planar type transistor”) as in the peripheral circuit transistor TP of the present invention described above (FIG. 8A). However, with a non-planar type transistor according to an embodiment of the present invention, an effective channel width can be increased due to its three-dimensional characteristic, compared to the planar type transistor, having a two-dimensional characteristic. As a result, the current driving capability of the phase-change memory device can be substantially improved.

Accordingly, with embodiments of the present invention, a larger current can flow than in a same-sized active area for a planar active structure, i.e., an increased drive current capability per a given active area.

In the above-described embodiments, a phase-change memory device having a non-planar channel region is fabricated by forming a trench in an active region of a semiconductor substrate to thereby form a fin structure protruding from a planar surface of the active region, which in turn form the non-planar channel region.

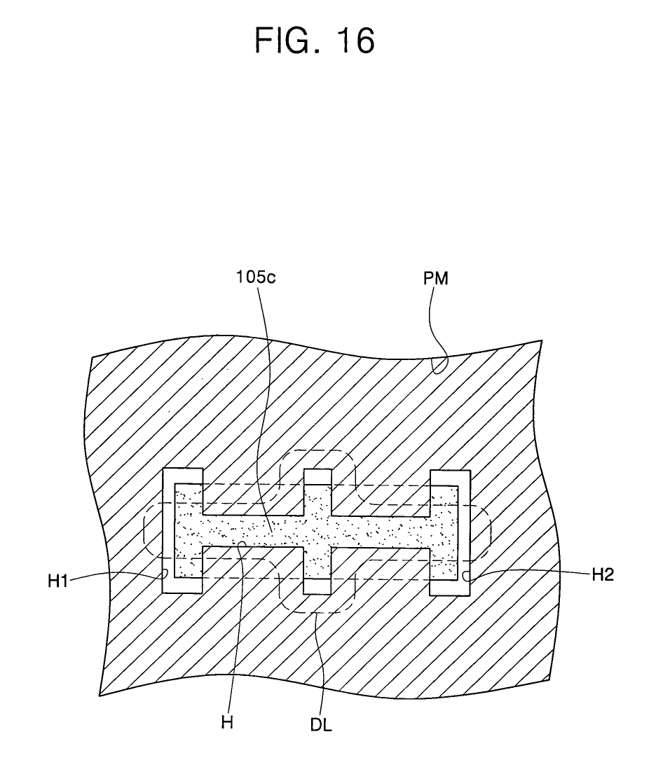

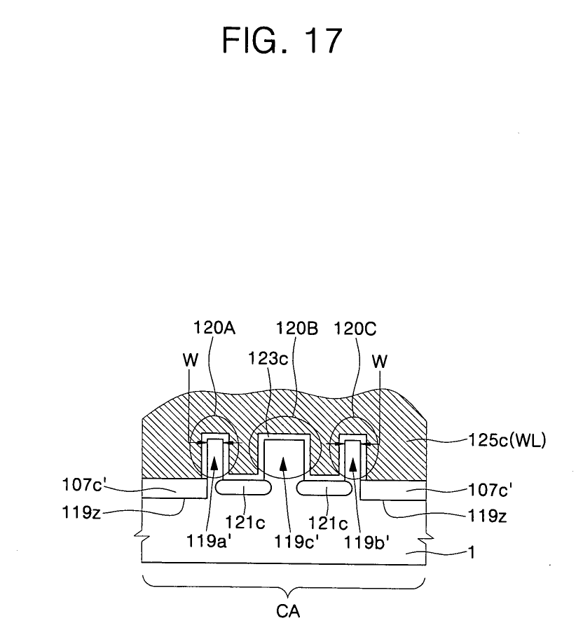

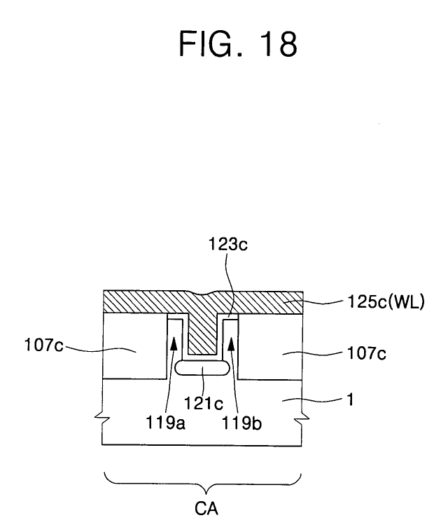

However, any other methods or non-planar structures having a three-dimensional characteristic, besides the above described methods, can be employed to form a non-planar surface or a non-planar channel region, as long as they provide a channel width greater than that of the conventional planar type transistor. For example, as shown in FIG. 17, using the mask pattern shown in FIG. 4C, more than two fin structures, e.g., triple fin structures having three fins protruding from a planar surface of the active region can be formed. The trench mask pattern 105c′ shown in FIG. 4C may be formed by a photoresist mask pattern PM shown in FIG. 16. The photoresist mask pattern PM includes an opening hole H in dashed line DL dividing the trench mask pattern 105c into four parts. Additional openings H1, H2. may be formed on the trench mask pattern 105c. Then, the trench mask pattern 105c is patterned using the photoresist mask pattern PM as an etch mask. In this case, multiple channel regions 120A, 120B, and 120C, each isolated by the channel stop layer 121c can be formed, instead of a single planar channel region as in the planar type transistor TP. As another example, as shown in FIG. 18, the trench isolation layer 107c may not be recessed. Also, the trench need not be formed to form a non-planar surface. In the alternative, although not shown in drawings, a hard mask pattern can be formed on an active region. Then, the active region is etched using the hard mask pattern as an etch mask. Next, the hard mask pattern is removed to form a fin structure protruding from the active region.

In addition, the resulting phase-change memory device further includes a molding layer 29 overlying a semiconductor substrate 1. The molding layer 29 has a protrusion portion 77 vertically extending from a top surface 67 of the molding layer 29. The protrusion portion 77 may have a thickness of at least 100 angstroms, preferably, in a range of about 300 to about 600 angstroms.

The memory device further includes a phase-changeable material pattern 37a adjacent to the protrusion portion 77 and a lower electrode 35 electrically connected to the phase-changeable material pattern 37a. The lower electrode 35 may extend through the protrusion portion 77, preferably along a center portion thereof. The protrusion portion 77 may be located above the first drain pad, i.e., conductive pad 27d′.

Further, the phase-changeable material pattern 37a may overlie the protrusion portion 77, although other configurations are also possible as long as the phase-changeable material pattern 37a is adjacent the protrusion portion 77 within the spirit and scope of the present invention.

Also, a sidewall of the phase-changeable material pattern 37a may be self-aligned with a sidewall of the protrusion portion 77. The phase-changeable material pattern 37a preferably comprises a chalcogenide material such as a GST (GeSbTe) alloy. According to an aspect of the present invention, the GST alloy may be doped by at least one of silicon and nitrogen.

The device may further include an upper electrode 39a electrically connected to the phase-changeable material pattern 37a.

Also, the device may include an oxidation barrier layer 48 covering at least a portion of a sidewall of the phase-changeable material pattern 37a and at least a portion of a sidewall of the protrusion portion. In one aspect, the oxidation barrier layer 48 may cover the phase-changeable material pattern 37a and the upper electrode 39a.

More particularly, the oxidation barrier layer 48 preferably covers an area where a sidewall of the phase-changeable material pattern 37a and a sidewall of the protrusion portion adjoin such that penetration of oxygen into the phase-change resistor 44a can be efficiently blocked. Consequently, with the embodiments of the present invention, a more reliable phase-change memory device can be formed in the present invention.

In another aspect of the present invention, the oxidation barrier layer 48 may comprise a first portion overlying a top of the upper electrode 39a and a second portion covering a sidewall of the phase-change layer pattern 37a. Although not illustrated in the drawing, the first portion has a thickness greater than the thickness of the second portion. Preferably, the thickness of the second portion is greater than or equal to about 300 angstroms.

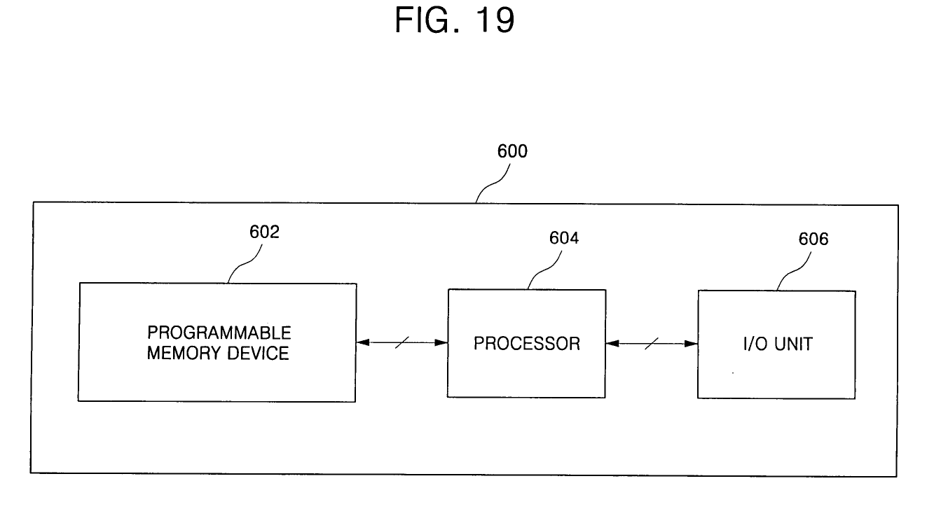

FIG. 19 shows a typical application of an embodiment of the invention. A portable electronic apparatus 600, such as a cell phone, utilizes a phase-change memory device 602 in conjunction with a processor 604 and an input/output device 606.

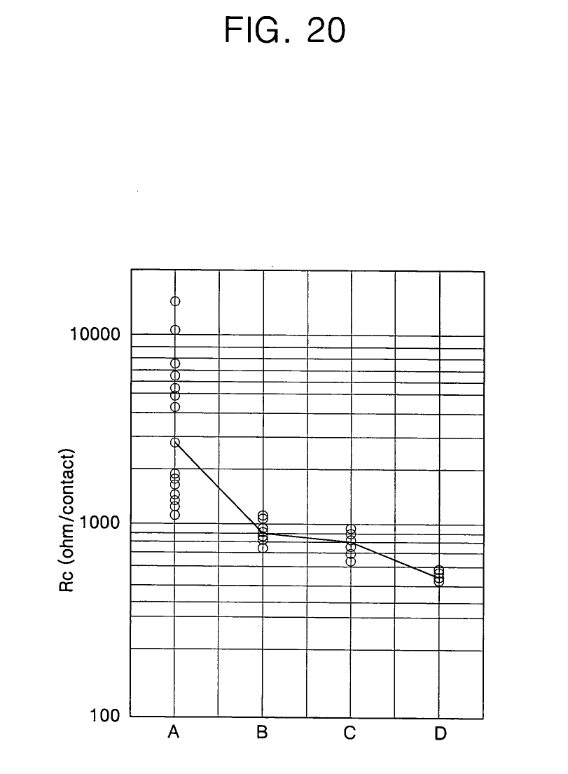

FIG. 20 is a plot showing a distribution of contact resistances for four samples, A, B, C, and D shown in Table 1 below.

TABLE 1

| | Prior art | Some of the examples of the present invention | | |
|---|---|---|---|---|
| process parameter | sample A | sample B | sample C | sample D |
| molding layer | silicon oxynitride (SiON) | | | |
| outer contact spacer | silicon oxynitride (SiON; plasma CVD) | | | |
| Inner contact spacer | silicon nitride (SiN; LP CVD) | | | |
| lower electrode | titanium nitride (TiN), diammeter: 50 nm) | | | |
| phase-change material | GeSbTe alloy | | | |
| upper electrode | titanium (TiN) | | | |
| oxygen barrier | None | SiON layer (200° C., | SiN layer 200° C., | lower SiN layer (200° C., |
| | | PECVD, 200 Å) | PECVD, 200 Å) | PECVD, 200 Å) |
| | | | | upper SiN layer (400° C., |
| | | | | PECVD, 200 Å) |

Sample A does not include an oxidation barrier layer, in contrast with the embodiments of the present invention. In FIG. 20 it is easy to see that the contact resistance for sample A has a much greater distribution than those of samples B, C, and D, each of which includes an oxygen barrier of various embodiments of the present invention.

Specifically, sample B comprises a SiON layer, sample C comprises a SiN layer, and sample D comprises a lower and an upper oxidation barrier layer, each of SiN. For sample B, the SiON layer is formed using a PECVD process at 200° C., to a thickness of 200Å. For sample C, the SiN layer is formed the same way as for sample B. For sample D, both SiN layers are formed as for samples B and C, except the upper layer is processed at 400° C.

FIG. 20 demonstrates the improvement over the conventional art, e.g., sample A, with the lower electrode contact resistances of phase-change resistors of samples B, C, and D showing very uniform distribution characteristics. The sample D among the samples manufactured by the invention has the most stable distribution characteristic.

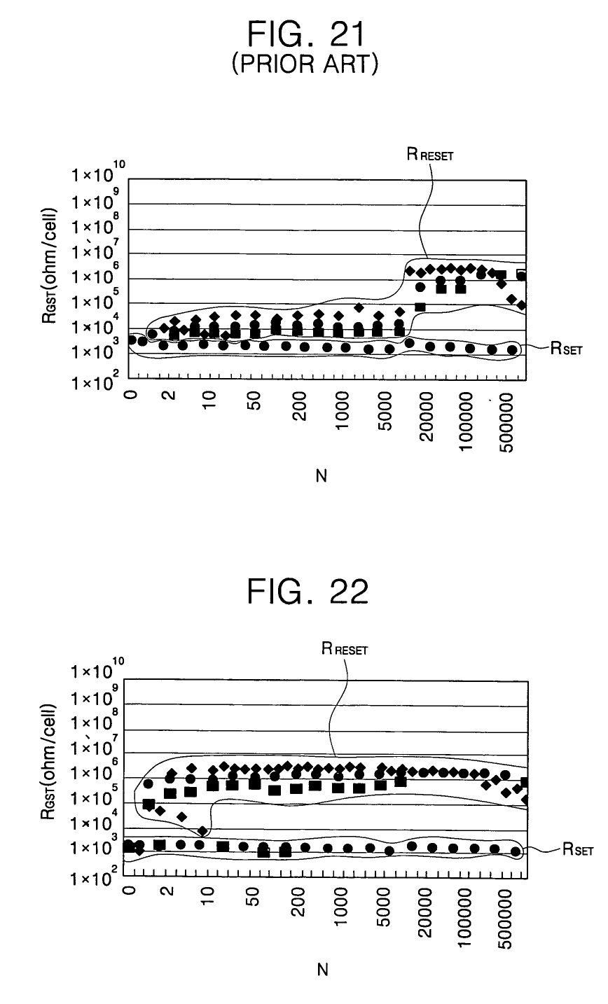

FIG. 21 is a graph showing programming characteristics of a conventional phase-change memory device without an oxidation barrier layer.

Up to about 5,000 programming cycles, a conventional phase-change memory device has a very low reset resistance value of 6,000-100,000 Ω, as compared with a set resistance value. Thus it is difficult to get enough sensing margin to read the memory cell information accurately.

FIG. 22 is a graph showing programming characteristic of a phase-change memory device of an embodiment of the present invention with an oxidation barrier layer. After 10 programming cycles, the phase-change memory device according to an embodiment of the invention has a very high reset resistance value of 30,000-3,000,000 Ω as compared with a set resistance value. Thus it has a very high sensing margin.

Comparing FIGS. 21 and 22, one can see that the interface region acting as a programming region of a phase-changeable material layer pattern of the present invention with an oxidation barrier layer has a better quality than that of a conventional phase-changeable material layer pattern.

Although the invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. A semiconductor device, comprising:
a semiconductor substrate having an isolation region that defines an active region, the active region having a planar surface and a non-planar surface that extends from the planar surface;
a gate dielectric layer covering the non-planar surface;
a first gate electrode extending across the non-planar surface with the gate dielectric layer therebetween to form a non-planar channel region;
a first impurity region and a second impurity region formed on opposite sides of the gate electrode,
wherein the non-planar channel region extends between the source region and the drain region, the non-planar channel region formed along the non-planar surface; and
a programmable resistance element electrically coupled to one of the first impurity and the second impurity region.

2. The device of claim 1, wherein the non-planar channel region comprises multiple channel regions separated by a channel stop layer.

3. The device of claim 1, further comprising a molding layer overlying the semiconductor substrate, wherein the programmable resistance element comprises:
a phase-changeable material pattern;
a lower electrode electrically coupled to the phase-changeable material pattern; and
an upper electrode electrically connected to the phase-changeable material pattern.

4. The device of claim 3, wherein the molding layer has a protrusion portion vertically extending from a top surface thereof and wherein the phase-changeable material pattern is disposed adjacent to the protrusion portion, the device further comprising:
an oxidation barrier layer covering an area where a sidewall of the phase-changeable material pattern and a sidewall of the protrusion portion adjoin.

5. The device of claim 3, wherein the phase-changeable material pattern comprises a chalcogenide material.

6. The device of claim 5, wherein the chalcogenide material comprises a GST (GeSbTe) alloy.

7. The device of claim 6, wherein the GST alloy is doped by at least one of silicon and nitrogen.

8. The device of claim 1, further comprising a peripheral circuit transistor having a second gate electrode and another source region and another drain region formed in a peripheral circuit active region having a planar surface, another source region and another drain region formed on opposite sides of the second gate electrode, the peripheral circuit transistor including a planar channel region extending between another source region and another drain region, the planar channel region formed along the planar surface.

9. The device of claim 8, wherein the width of the second gate electrode is different from that of the first gate electrode.

10. The device of claim 9, wherein the width of the second gate electrode is greater than that of the first gate electrode.

11. The device of claim 10, wherein the width of the second gate electrode is at least about 1.5 times greater than the width of the first gate electrode.

12. The device of claim 8, wherein the first gate electrode has a first gate dielectric disposed thereunder, and wherein the second gate electrode has a second gate dielectric disposed thereunder, the thickness of the first and second dielectrics being not equal.

13. The device of claim 12, wherein the thickness of the second gate dielectric is greater than that of the first gate dielectric.

14. A semiconductor device, comprising:
a semiconductor substrate;
an isolation region formed in the substrate, the isolation region defining an active region;
at least one fin structure formed on the semiconductor substrate, the fin structure protruding from a surface of the active region;
a gate dielectric layer conformally covering the at least one fin structure;
a gate electrode extending across the at least one fin structure;
a source region and a drain region formed in the active region, the source region and the drain region formed on opposite sides of the gate electrode; and
a variable resistor electrically connected to the drain region.

15. The device of claim 14, wherein the at least one fin structure forms a non-planar channel region extending between the source region and the drain region.

16. The device of claim 14, wherein the at least one fin structure forms multiple channel regions separated by a channel stop layer, the multiple channel regions extending between the source region and the drain region.

17. The device of claim 14, wherein the gate electrode covers an upper surface and at least one sidewall of the at least one fin structure with the gate dielectric layer disposed therebetween.

18. A semiconductor device, comprising:
a semiconductor substrate comprising:
first channel fins spaced from each other and protruding from the substrate, the first channel fins each having an upper surface and sidewalls;
a gate dielectric layer covering the upper surface and the sidewalls;
a first gate extending across the first channel fins, the first gate overlying the upper surface and the sidewalls with the gate dielectric layer disposed therebetween;
a first impurity region and a second impurity region formed on opposite sides of the first gate; and
a programmable resistance element electrically connected to one of the first impurity region and the second impurity region.

19. The device of claim 18, wherein the first gate covers a region between the first channel fins and overlies a portion of the gate dielectric layer.

20. The device of claim 19, further comprising a channel stop layer formed at the region between the first channel fins and disposed below the gate dielectric layer.

21. The device of claim 18, wherein the width of one of the first channel fins is less than photolithography resolution limit.

22. The device of claim 18, wherein the programmable resistance element comprises:
a phase-change material layer sandwiched between a lower electrode and an upper electrode.

23. The device of claim 22, wherein the phase-change material comprises a chalcogenide.

24. The device of claim 23, wherein the chalcogenide comprises N or Si doped GeSbTe.

25. The device of claim 22, further comprising;
a molding layer covering the first gate and first and second impurity regions, the molding layer having a protrusion portion vertically extending from a top surface thereof and wherein the programmable resistance element is disposed adjacent to the protrusion portion, and
an oxygen barrier covering an area where a sidewall of the phase-change material layer and a sidewall of the protrusion portion adjoin.

26. The device of claim 25, wherein the lower electrode extends through the protrusion portion.

27. The device of claim 18, further comprising:
second channel fins protruding from the semiconductor substrate;
a first connection portion connecting the first channel fins and the second channel fins;
a second gate extending across the second channel fins with another gate dielectric layer disposed therebetween;
a third impurity region formed adjacent the second gate in the semiconductor substrate; and
a second programmable resistance element electrically connected to the third impurity region.

28. The device of claim 18, further comprising a peripheral circuit region that includes a third gate and a source/drain region formed on opposite sides of the third gate, the third gate located on a planar surface of the substrate.

29. A system comprising:
a processor;
input and output in communication with the processor; and
a phase-change memory device in communication with the processor, the device including:
a semiconductor substrate having an isolation region that defines an active region, the active region having a planar surface and a non-planar surface that extends from the planar surface;
a gate dielectric layer covering the non-planar surface;
a first gate electrode extending across the non-planar surface with the gate dielectric layer therebetween to form a non-planar channel region;
a source region and a drain region formed on opposite sides of the gate electrode,
wherein the non-planar channel region extends between the source region and the drain region, the non-planar channel region formed along the non-planar surface; and
a programmable resistance element electrically coupled to the drain region

30. The system of claim 30, wherein the processor is a digital signal processor (DSP) or a central processing unit (CPU).

31. A method of manufacturing programmable memory device, the method comprising:
providing a semiconductor substrate having a planar surface;
forming a non-planar surface extending from the planar surface on the semiconductor substrate;
forming a gate dielectric layer overlying the non-planar surface;
forming a gate extending across the non-planar surface with the gate dielectric layer disposed therebetween;
forming a first impurity region and a second impurity region on opposite sides of the gate; and
forming a programmable resistance element electrically coupled to one of the first and second impurity regions.
